(19) United States
(12) Patent Application Publication
(10) Pub. No.: US 2023/0240145 A1
(43) Pub. Date: Jul. 27, 2023

(54) PIEZOELECTRIC ENERGY GENERATOR

(71) Applicant: Lucas Wayne Ridings, Shawnee, KS (US)

(72) Inventor: Lucas Wayne Ridings, Shawnee, KS (US)

(21) Appl. No.: 18/159,577

(22) Filed: Jan. 25, 2023

Related U.S. Application Data
(60) Provisional application No. 63/267,110, filed on Jan. 25, 2022.

(51) Int. Cl. H10N 30/30; H10N 30/88; H10N 30/80

(52) U.S. Cl. CPC H10N 30/30; H10N 30/88; H10N 30/802

(57) ABSTRACT

A piezoelectric energy generator for a stadium, auditorium or other venue includes one or more tiles or mats, with each tile having one or more piezoelectric transducer devices formed therein such that voltage and current are generated when pressure is applied to the piezoelectric transducers, such as by people walking or stomping on the tiles. The tiles and piezoelectric devices are interconnected and connected to centrally located control and conditioning circuitry, which conditions the generated electricity for usage, storage, or transmission to an external power grid.

### CROSS-REFERENCE TO RELATED APPLICATIONS

This application claims the benefit of U.S. Provisional Patent Application No. 63/267,110, filed Jan. 25, 2022, the disclosure of which is hereby incorporated herein in its entirety by reference.

### FIELD

The present invention relates generally to electrical power generation, and more particularly to converting kinetic energy to electrical power using tile devices having integrated piezoelectric transducers.

### BACKGROUND

The piezoelectric energy generator of present invention relates generally to electrical power generation, supply, collection, and use, by capitalizing on available kinetic energy through the conversion and modification of electrical power accordingly using a system of specifically designed surface casing devices integrated with piezoelectric transducers. This system is especially useful when integrated throughout public auditoriums, venues, arenas, and stadiums of all sizes by producing innovative solutions to meet high demands for energy.

As recent technological advancements through research and development with experimentation and implementation of renewable and efficient energy power generation systems have expanded and created an entirely new and unique market of their own, respective industries have gained increasing favorability towards implementation of such renewable and low emissions solutions to provide electrical power in various venues. As these sectors continue to increase in profitability and feasibility, analogous demand pertinent to state and national agendas provide clear needs to be met.

Present renewable energy resources (wind, solar, hydroelectric, etc.) work together in part to provide many electrical needs but have yet to fulfill the high demand required by growing populations in its entirety. Thus, the stage is set for a new tactical system and methodology to work conjointly with existing green energy technologies and help meet the goals and needs on state and national levels. Many businesses, venues, and sectors will benefit from locally implemented electrical solutions such that reliance on an external grid to supply power may no longer be necessary.

Many businesses, venues, and sectors will benefit from locally implemented electrical generation solutions, reducing sole reliance on an external power grid to supply power and freeing up previously allocated resources amongst the community. Thus, while individual venues currently rely primarily on external power grids, there remain untapped sources of energy available within these venues that would allow greater operational independence.

### SUMMARY

Embodiments of the invention are defined by the claims below, and are not to be restricted in any way here by this summary. A high-level overview of various aspects of the invention is provided here to introduce a selection of concepts that are further described in the detailed description section below. This summary is not intended to restrict or limit any potential applications, variations, or custom configurations identifiable through the key features or essential features of the claimed subject matter, nor is it intended to be used in isolation to determine the scope of the claimed subject matter. In brief, this disclosure describes, among other things, a piezoelectric power generation system for use in stadiums, auditoriums, and the like.

The present invention is directed to a system and method for generating energy in the form of usable electricity through the harvesting and conversion of kinetic energy (e.g., force and pressure produced by the natural gravitational weight of foot traffic throughout civilian infrastructure) within a building or venue, such as an auditorium or stadium.

In one embodiment, a plurality of surface casings, also referred to as “tiles”, each having a plurality of piezoelectric plates or discs embedded or attached therein, are configured and arranged to cover the walking, seating space, and foot traffic areas within a venue. The piezoelectric plates or discs within an individual surface casing unit are interconnected to provide for an electrical output, with multiple casings similarly interconnected such that the individual piezoelectric plates or discs are ultimately arrayed across a vast, interconnected arrangement. Voltage and current are generated when pressure of any kind is applied to the piezoelectric plates or discs; the interconnected array of tiles placed beneath the appropriate foot traffic paths provides for reception of the multiple continuous points of force-impact on the piezo elements by patrons in the venue providing the continuous movement and activity engaging the tiles.

In one embodiment, the interconnected array of tiles is connected to control and conditioning circuitry that converts the generated voltage and currents to a desired state for use such that the generated energy can be consumed directly by the venue, for example to power signage, speakers, overhead lighting, climate control if applicable, and is unlimited in other electrical components. In other embodiments, the generated energy may be stored in a battery bank system, and/or may be transmitted into the electrical grid such that an allocated portion of energy generated may be sold and used amongst the community. Implementation in venue locations found to experience the optimum frequency of foot traffic patterns will produce the most efficient output levels, finding this technology a home as a stable, reliable energy production method on both the large- and small-scale levels.

In one aspect, an individual tile having a plurality of interconnected piezoelectric plates or discs generates electricity when a force (such as the force of a patron walking or stomping on the tile) is applied to the tile, with the individual tile thus generating a voltage and current. In another aspect, a plurality of tiles are interconnected, with dozens, hundreds, or thousands of tiles within a venue connected in series or parallel and further connected to control and conditioning circuitry which provides for capturing and storing the generated energy, such as in a battery, capacitor, or other electrical storage device. In another aspect, the control and conditioning circuitry allows the generated electricity to be output to an external electrical grid so that excess electricity may be used elsewhere and/or so that the excess electricity may be sold by the venue.

In other embodiments, tiles having piezoelectric elements may be used in other indoor or outdoor venues, such as stadiums, auditoriums, and other locations with significant foot traffic, designed to seamlessly integrate into the existing infrastructure.

Thus, the generated electricity may be used as it is generated to power signage, appliances, lighting, and other electrical apparatus within the venue, or the generated electricity may be stored in one or more electrical storage devices, or it may be provided to an external electrical grid.

In one aspect, the apparatus of the present invention enables the production of electricity at no periodically recurring cost to users. Electricity consumption is significantly more efficient if generated at the source of usage as opposed to an external source location and having the need to be transferred over a greater distance such as is done in previously established methods. This invention uses a naturally occurring and reoccurring source (i.e., the force generated from the applied pressure of an object's natural gravitational weight, such as people walking, stomping, or moving) as an additional method to power buildings and infrastructure in communities. Current traditional renewable energy methods such as solar, wind, hydro, etc., face barriers in finding useful application on a larger scale in cities and urban infrastructure because of their reliance on particular natural elements restricted to specific locations. By making use of this available kinetic energy from pedestrian traffic throughout cities, this invention broadens the current demographic spectrum of renewable electricity technology for states while producing and delivering power amongst high population density regions.

In comparison to other devices using piezoelectric technology as a means for electricity generation advantageous to the location, the apparatus of the present invention is able to make use of available points of force impact by meeting the movement where it is known to occur as opposed to waiting in place for an object of mass to pass by. This is achieved through placement of the piezo transducers directly in front of and beneath each member or traffic area in the auditorium. By meeting the energy source directly where it will be occurring, electricity is able to be produced at a quicker pace and at a much more efficient rate than other known renewable energy sources.

### DESCRIPTION OF THE DRAWINGS

FIG. 1 is a perspective view of a tile having a plurality of interconnected piezoelectric elements arranged therein in accordance with an exemplary embodiment of the present invention.

FIG. 2 is a plan view of a plurality of tiles as in FIG. 1 arranged in side-by-side rows and in electrical communication in accordance with an exemplary embodiment of the present invention.

FIG. 3 is a plan view of a plurality of tiles as in FIG. 1 interconnected in electrical communication in accordance with an exemplary embodiment of the present invention.

FIG. 4 is a schematic diagram of exemplary control and conditioning circuitry connected to a plurality of piezoelectric elements in accordance with an exemplary embodiment of the present invention.

FIG. 5 is a perspective view of a plurality of tiles as in FIG. 1 placed in position in an aisle of seats in a stadium venue.

FIG. 6 is a perspective view of rows of tiles as in FIG. 1 positioned in multiple rows of a stadium venue.

FIG. 7 is a block diagram of a system for capturing electrical energy from piezoelectric elements in accordance with an exemplary embodiment of the present invention.

### DETAILED DESCRIPTION

The subject matter of select embodiments of the invention is described with specificity herein to meet statutory requirements. But the description itself is not intended to necessarily limit the scope of claims. Rather, the claimed subject matter might be embodied in other ways to include different components, steps, or combinations thereof similar to the ones described in this document, in conjunction with other present or future technologies. Terms should not be interpreted as implying any particular order among or between various steps herein disclosed unless and except when the order of individual steps is explicitly described. The terms “about” or “approximately” as used herein denote deviations from the exact value in the form of changes or deviations that are insignificant to the function.

Embodiments of the invention include devices, systems, and methods for generating electricity using interconnected piezoelectric elements, such as piezoelectric plates or discs, embedded or placed within resilient tiles, with the electrical output of each of the elements interconnected such that each tile provides an electrical output. Multiple tiles are likewise electrically interconnected, with rows, aisles, and/or sections of flooring within a venue covered by the interconnected tiles so that the combined electrical output of the plurality of interconnected tiles is provided to control and conditioning circuitry for powering electrical apparatus within the venue (such as lighting, signage, and the like), for storing the generated electrical power in a battery or capacitor bank, and for directing the generated electrical power onto an external electrical power grid.

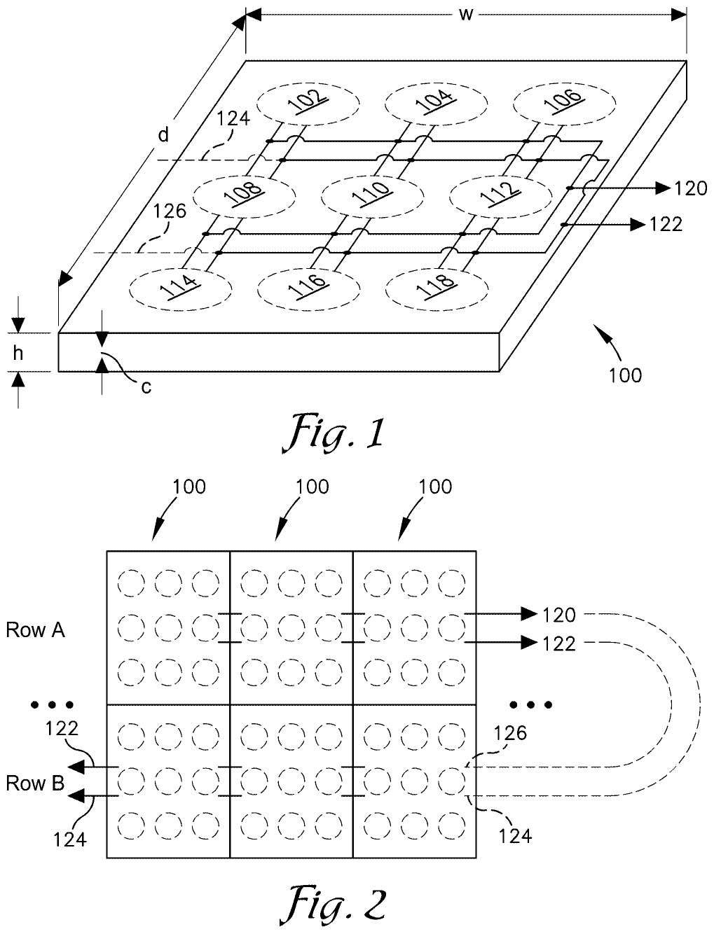

Looking first to FIG. 1, a tile (or mat, as used interchangeably herein) comprising a plurality of piezoelectric transducers in accordance with an exemplary embodiment of the present invention is depicted generally by the numeral 100. Tile 100 is generally square in shape, having a width w and depth d, as well as a height h. As seen in the figure, the tile 100 is preferably slightly compressible c so that weight or force on the upper surface of the tile causes the tile to flex or compress slightly. A plurality of disc-shaped piezoelectric elements (102, 104, 106, 108, 110, 112, 114, 116, 118) are arranged in a grid pattern within the tile 100, with each piezoelectric element operable to generate an electrical voltage and current when deflected—such as the by the force imparted by a person walking or stomping on the tile. Each of the piezoelectric elements are interconnected by electrical wiring, with the interconnected wiring exiting the side of the tile 100, with electrical connections 120, 122 available to connect the tile to additional tiles or to transmission lines to allow electrical energy generated by the tile to be routed to centrally located control and conditioning circuitry for conditioning the generated electricity.

Piezoelectric elements (102-118) and interconnecting wiring are preferably embedded within the body of the tile 100, and may be formed therein (i.e., placed within the tile as the tile is being formed), or may be placed within receptacles formed in the tile after manufacture, such that the piezoelectric elements and interconnecting wiring are protected within the tile body. Most preferably, tile 100 is manufactured of a water and weatherproof, or water and weather resistant, material.

As also seen in FIG. 1, tile 100 may include input electrical lines 124, 126, to allow electrical connection to an adjacent tile having output electrical lines 120, 122. Thus, multiple tiles can be cascaded together, with the electrical output of one tile feeding into and connecting to the electrical input of an adjacent tile. Thus, as will be explained in more detail below, an entire row of tiles can be connected together, with the output of one tile providing a connection to power transmission lines to propagate any and all of the electrical energy generated by any or all of the tiles thus connected.

It should be understood that the embodiment depicted in FIG. 1 is exemplary, and that other variations are contemplated within the scope of the present invention. For example, while the embodiment depicted in FIG. 1 includes nine disc-shaped piezoelectric elements arranged in a grid pattern, in other embodiments the number of elements may be greater or less, and the shape of the piezoelectric elements may be square, or any other shape.

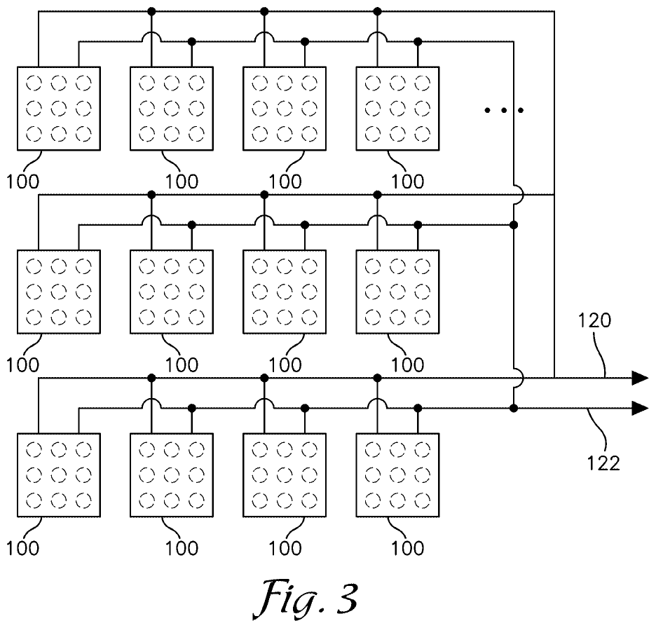

Turning to FIG. 2, a plurality of tiles 100 are depicted in adjacent arrangement in two rows, with the electrical output of one tile feeding into the electrical input of an adjacent tile as previously described. As seen in the figure the electrical output 120, 122 of the three interconnected tiles of row A are connected to the electrical input 122, 124 of the three interconnected tiles of row B such that an electrical output 122, 124 of the final tile of row B comprises the electrical energy of all of the interconnected tiles of row A and row B. It should be understood that the depiction in FIG. 2 is exemplary, and that additional tiles may be included in each row, and that more rows may be included, and likely would be included in a stadium or arena venue.

It should be further understood that the electrical inputs and outputs of the tiles 100 may be arranged in any desired series or parallel arrangement to accommodate any desired voltage output from a group of interconnected tiles. Thus, while FIG. 2 depicts a plurality of tiles 100 interconnected in series, turning to FIG. 3, it can be seen that the tiles may likewise be interconnected in parallel arrangement, with multiple rows of tiles 100 interconnected with electrical outputs 120, 122 providing connection points to attach to transmission lines for propagating the generated electrical energy to a central location as previously described. It should be apparent to those skilled in the art that any desired combination of parallel and series connection of groups of tiles may be implemented to provide a desired voltage and/or current output. For example, an entire section of rows within a venue may be fitted with tiles connected in series as depicted in FIG. 2, with multiple sections further connected in parallel with each other to achieve a desired voltage and/or current output. These and other variations are within the scope of the present invention.

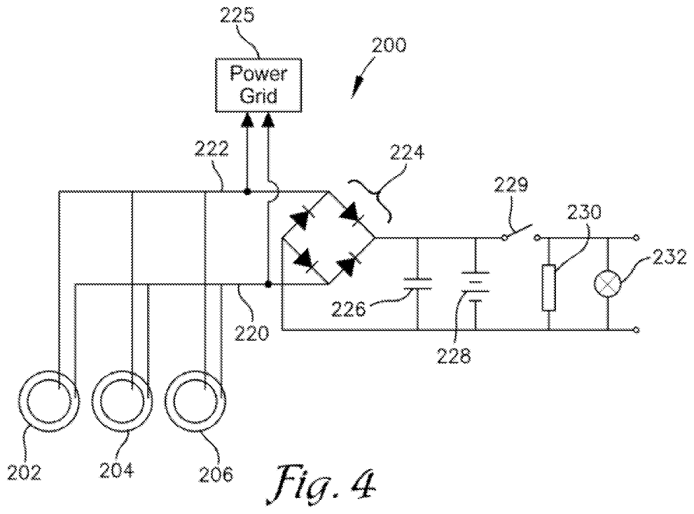

Turning now to FIG. 4, control and conditioning circuitry for use in conjunction with the piezoelectric elements and tiles of the present invention is depicted generally by the numeral 200. As depicted in FIG. 4, a plurality of piezoelectric elements 202, 204, 206, are connected in parallel arrangement, with the outputs 220, 222 of the interconnected elements in electrical communication with a bridge rectifier 224. As is known in the art, the bridge rectifier converts the input alternating current (AC) to a direct current (DC). The DC power may then be applied to a capacitor 226 and/or battery 228 which can store the electrical energy generated by the piezoelectric elements 202, 204, 206.

Generated power may also be provided to an external power grid 225, such that the generated AC power may be tapped from the outputs 220, 222 of the interconnected piezo electric devices and provided and/or sold for distribution across the external grid 225. In a preferred embodiment, the control and conditioning circuitry 200 includes the appropriate interface and conditioning circuitry for interface with the external power grid 225, such as isolation circuitry, transfer switches, and the like.

As further seen in FIG. 4, a switch 229 is operable to direct the DC power—either directly from the bridge rectifier 224, the capacitor 226, and/or the battery 228—to electrical devices 230 and 232, which may be any type of lighting, display, or other electrically powered device. Thus, as can be seen, the electrical energy generated by the piezoelectric elements may be used directly to power electrical devices, or the energy may be stored in a bank of supercapacitors or batteries for use on demand.

It should be understood that the control and conditioning circuitry 200 as depicted in FIG. 4 is exemplary, and that the size and scale of the circuitry may be adapted as necessary to accommodate large venues as contemplated by the present invention. For example, in exemplary embodiments, the capacitor 226 may be a bank or banks of supercapacitors to store large amounts of electrical energy, and battery 228 may be a bank or banks of batteries. Thus, as described previously, an entire section of seating in a venue, with tiles placed in each row, may be interconnected and connected to control and logic circuitry as in FIG. 4. And ultimately, an entire stadium, filled with rows of seating, with each seat having a tile, may be interconnected to a central power station comprising control and conditioning circuitry 200 for storing and routing the electrical energy. That energy may be used directly to power electrical devices such as lamps, lighting, display screens, and scoreboards, may be stored in banks of supercapacitors or batteries for later usage on demand, or may be transmitted to an external power grid with the venue thus obtaining revenue from the excess generated electricity.

In alternative embodiments, the control and conditioning circuitry 200 may be centrally located, or may be dispersed, for example with a small electrical station comprising control and conditioning circuitry for a single section of tiles within the venue, with those smaller electrical stations further connected to a larger central station. These and other arrangements and configurations are within the scope of the present invention.

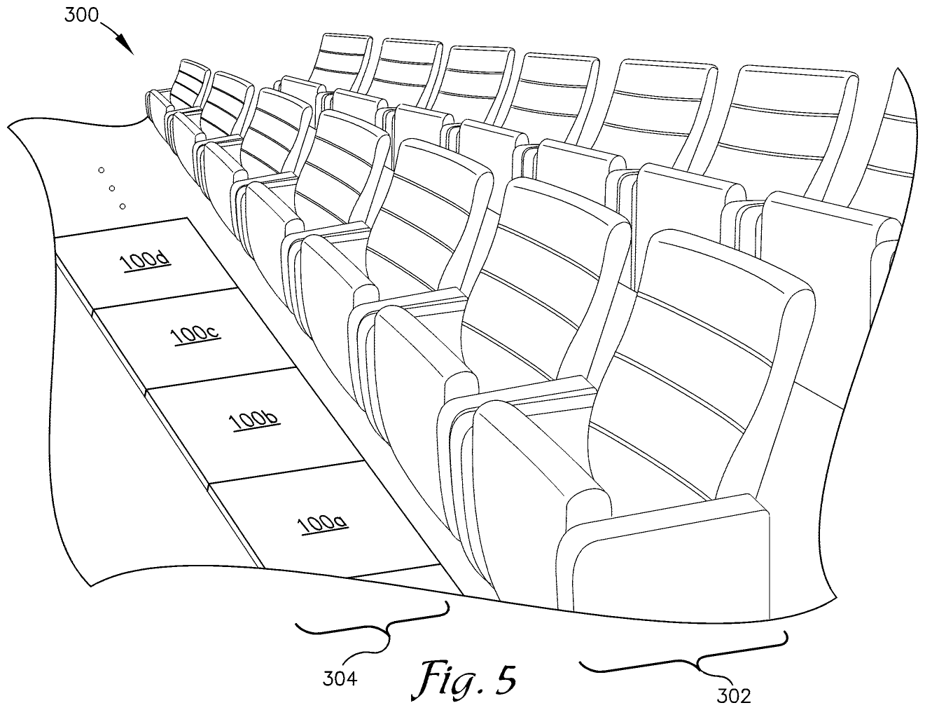

Looking to FIG. 5 in conjunction with FIG. 1, a plurality of tiles 100a, 100b, 100c, 100d are depicted positioned in side-by-side arrangement in a row at a stadium or auditorium venue, generally designated as element 300. As depicted, each tile is configured to substantially cover the aisle area in front of a corresponding seat, with a row of tiles 304 corresponding to the row of seating 302. As described previously, the plurality of tiles 100a, 100b, 100c, 100d, are electrically interconnected, with each tile in electrical communication with the adjacent tiles so that generated electricity can be propagated along the row of tiles and eventually to control and conditioning circuitry.

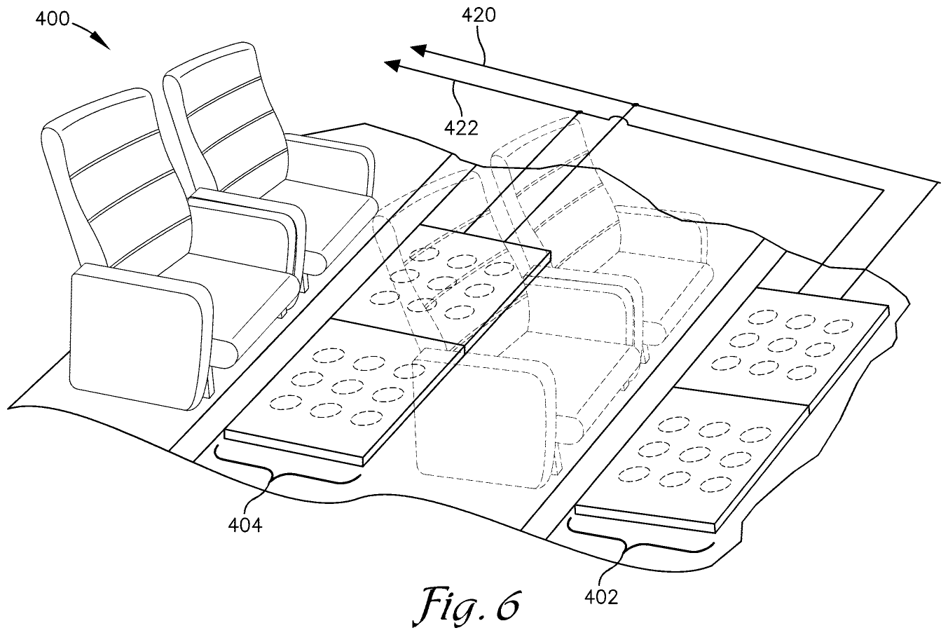

Turning to FIG. 6, an arrangement of rows of tiles connecting to transmission lines is depicted generally as 400. Two rows of interconnected tiles 402, 404 are connected to transmission lines 420, 422 so that generated electricity may be transmitted through the row of tiles and to the transmission lines, which further propagate the generated electricity to centrally located control and conditioning circuitry as previously described.

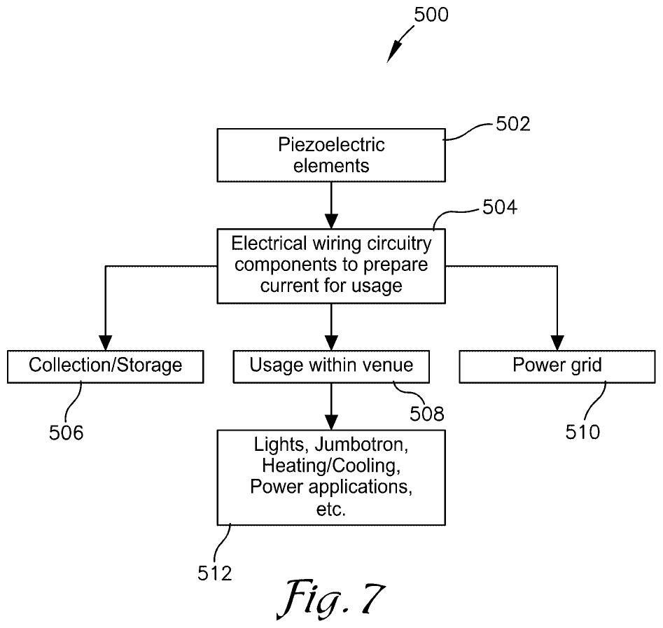

A block diagram of the piezoelectric tile and electrical energy generating system of the present invention is depicted in block diagram 500 of FIG. 7. As seen in FIG. 7, at block 502, individual piezoelectric elements are placed in tiles for installation in aisles, rows, and other walking areas of a venue. At block 504, the tiles are connected to electrical wiring and to control and conditioning circuitry which conditions the generated electricity for usage. At block 506, the generated electricity may be stored in a bank (or banks) of supercapacitors, batteries, or other electrical storage devices. At block 508, the generated electricity may be used directly by the venue, such as at block 512 to operate lighting, heating/cooling, scoreboards, jumbotrons, displays, or any other electrically powered device. At block 510, the generated electricity may be sold and transmitted to an external power grid for use beyond the venue where the electricity was generated.

Thus, as set forth herein, it can be seen that the piezoelectric energy generator of the present invention is well-suited for installation in any venue in which multiple people may be congregating, with any movement of those people walking, stomping, or moving on the tiles will be converted to corresponding electrical energy which can be immediately used, stored, or sold by the venue. While the usage of the invention has been described with respect to venues such as stadiums, auditoriums, and the like, it should be understood that the tiles of the present invention may be configured for installation and interconnection in other venues, such as walkways and seating areas in airports, concourses in venues, walkways and stairways interconnecting buildings, and any other venue or area in which large numbers of people may congregate or travel.

1. A piezoelectric energy generator, comprising:
a resilient tile comprising a main body portion having a height, width, and depth, wherein the main body portion is compressible; and
one or more piezoelectric transducers positioned within the main body portion of the tile such that the transducers flex and generate electricity when a corresponding portion of the main body portion is compressed by an external force, wherein the one or more piezoelectric transducers are electrically interconnected such that electricity generated by any one of the one or more piezoelectric transducers is propagated to an electrical output of the tile.

2. The piezoelectric energy generator of claim 1, wherein the one or more piezoelectric transducers comprises a plurality of piezoelectric transducers.

3. The piezoelectric energy generator of claim 1, wherein the main body portion of the tile is waterproof and wherein the one or more piezoelectric transducers are embedded within the main body portion.

4. The piezoelectric energy generator of claim 1, further comprising an electrical output in communication with the one or more piezoelectric transducers and operable to propagate generated electrical power from the tile.

5. The piezoelectric energy generator of claim 4, further comprising an electrical input operable to receive an electrical output from an adjacent tile.

6. The piezoelectric energy generator of claim 1, wherein the main body portion of the tile is configured to attach to a main body portion of a second adjacent tile.

7. The piezoelectric energy generator of claim 1, further comprising:
control and conditioning circuitry operable to receive electrical energy from an electrical output of the tile and to distribute the electrical energy to electrical devices.

8. The piezoelectric energy generator of claim 7, wherein the electrical devices comprise: devices within the venue, energy storage devices, an external power grid, and combinations thereof.

9. The piezoelectric energy generator of claim 8, wherein the energy storage devices comprise supercapacitors, batteries, banks of supercapacitors, banks of batteries, and combinations thereof.

10. A piezoelectric energy generator, comprising:
a plurality of resilient tiles, each having a compressible main body portion;
wherein each of the plurality of resilient tiles comprises a plurality of piezoelectric transducers positioned within the corresponding main body portion tile such that the piezoelectric transducers flex and generate electricity when a corresponding portion of the main body portion is compressed by an external force; and
wherein the plurality of piezoelectric transducers within each tile are electrically interconnected and wherein an electrical output of each of the plurality of resilient tiles is connected to a transmission line for propagating generated electricity to control and conditioning circuitry.

11. The piezoelectric energy generator of claim 10, wherein the main body portion of each of the plurality of tiles is waterproof and wherein the corresponding plurality of piezoelectric transducers are embedded within the main body portion.

12. The piezoelectric energy generator of claim 10, wherein each of the plurality of tiles comprises an electrical input operable to receive an electrical output from an adjacent tile.

13. The piezoelectric energy generator of claim 1, wherein the main body portion of each tile is configured to attach to a main body portion of an adjacent tile.

14. The piezoelectric energy generator of claim 10, wherein the control and conditioning circuitry is operable to distribute electrical energy to electrical devices within a venue.

15. The piezoelectric energy generator of claim 14, wherein the electrical devices within a venue comprise: lighting devices, display devices, energy storage devices, an external power grid, and combinations thereof.

16. The piezoelectric energy generator of claim 15, wherein the energy storage devices comprise supercapacitors, batteries, banks of supercapacitors, banks of batteries, and combinations thereof.

17. A piezoelectric energy generator, comprising:
a plurality of tiles, each comprising a plurality of piezoelectric transducers positioned within a main body of the corresponding tile such that the piezoelectric transducers flex and generate electricity when a corresponding portion of the main body portion is compressed by an external force; and
wherein the plurality of piezoelectric transducers within each tile are electrically interconnected and wherein an electrical output of each of the plurality of resilient tiles is connected to a transmission line for propagating generated electricity to control and conditioning circuitry.

18. The piezoelectric energy generator of claim 17, wherein a main body portion of each of the plurality of tiles is waterproof and wherein the corresponding plurality of piezoelectric transducers are embedded within the main body portion.

19. The piezoelectric energy generator of claim 10, wherein each of the plurality of tiles comprises an electrical input operable to receive an electrical output from an adjacent tile.

20. The piezoelectric energy generator of claim 17, further comprising:
control and conditioning circuitry operable to receive electrical energy from an electrical output of the plurality of tiles and to distribute the electrical energy to electrical devices.
